(19) United States
(12) Patent Application Publication
(10) Pub. No.: US 2016/0234952 A1
(43) Pub. Date: Aug. 11, 2016

(54) DEVICE FOR SHIELDING ELECTRONICS FROM THERMAL, ULTRAVIOLET, AND ENVIRONMENTAL EXPOSURE

(71) Applicant: Rodolfo Lozano, IV, Laredo, TX (US)

(72) Inventor: Rodolfo Lozano, IV, Laredo, TX (US)

(21) Appl. No.: 15/019,102

(22) Filed: Feb. 9, 2016

Related U.S. Application Data
(60) Provisional application No. 62/176,029, filed on Feb. 9, 2015.

(51) Int. Cl. H05K 5/06; H05K 9/00; H05K 7/20; F16M 13/02

(52) U.S. Cl. CPC H05K 5/06; F16M 13/02; H05K 9/00; H05K 7/20509

(57) ABSTRACT

Devices and methods for a device for shielding electronics from thermal, ultraviolet, and environmental exposure are disclosed herein. The present invention is directed to shading and shielding electronic devices mounted on a wall such as, but not limited to, cameras, transmitters, electronics and the accompanying power/data cabling from deteriorating ultraviolet, thermal radiation, and glare. The device also enhances video by keeping direct sunlight off the lens of video electronics while also extending the overall effective operating lifespan of the electronic device. In embodiments, the device has a parabolic shape to act as a directional wave amplifier to increase the range of communication electronics and transmitters. In an embodiment, the device is comprised of a wall back plate element and a shielding top plate element.

### CROSS-REFERENCE TO RELATED APPLICATIONS

This application claims the benefit under Title 35 United States Code §119(e) of U.S. Provisional Patent Application Ser. No.: 62/176,029; Filed: Feb. 9, 2015, the full disclosure of which is incorporated herein by reference.

### STATEMENT REGARDING FEDERALLY SPONSORED RESEARCH OR DEVELOPMENT

Not applicable

### THE NAMES OF THE PARTIES TO A JOINT RESEARCH AGREEMENT

Not applicable

### INCORPORATING-BY-REFERENCE OF MATERIAL SUBMITTED ON A COMPACT DISC

Not applicable

### SEQUENCE LISTING

Not applicable

### FIELD OF THE INVENTION

The present invention relates generally to devices and methods for shielding electronic devices. More specifically, the present invention relates to devices and methods for shielding electronic devices from the direct exposure to thermal and ultraviolet radiation as well as adverse environmental conditions.

### BACKGROUND OF THE INVENTION

Without limiting the scope of the disclosed device and method, the background is described in connection with devices and methods directed to shielding electronics from thermal, ultraviolet, and environmental exposure.

Currently there are a number of devices for shielding electronics such as camera enclosures in the prior art. However, these prior art devices are heavy, bulky, expensive, difficult to install, and also tend to become fogged up with moisture thereby seriously degrading the recording of the images being captured. The fogginess usually occurs when the enclosure has been exposed to the elements for years, but can also occur with very heavy downpours or repeated exposure to rainy, foggy or extremely humid conditions. The devices in the prior art also do not allow for easy replacement of damaged parts.

It would be desirable to have a low cost, universal camera/electronics shade available as an alternative to expensive camera enclosures that require extensive mounting times and are custom made towards particular camera sizes and shapes.

In view of the foregoing, it is apparent that there exists a need in the art for an electronic shielding device, which overcomes, mitigates, or solves the above problems in the art. It is the purpose of this invention to fulfill this and other needs in the art, which will become apparent to the skilled artisan once given the following disclosure.

### BRIEF SUMMARY OF THE INVENTION

The present invention, therefore, provides for devices and methods directed to shielding electronics from thermal, ultraviolet, and environmental exposure.

In one embodiment, the device is comprised of a wall back plate element and a shielding top plate element. The wall back plate element and the shielding top plate element are connected and form, in an embodiment, a right angle to each other. The upper portion of the wall back plate element is connected to the back portion of the shielding top plate element. In embodiments, the electronic device being protected is mounted directly to the electronics shielding device. In other embodiments, the electronic device being protected is mounted near and under the electronics shielding device.

The device may be scaled up and down by changing the size and shape of the elements to meet various applications and electronic device sizes.

In summary, the present invention discloses devices and methods for shielding electronic devices. More specifically, the present invention relates to devices and methods for shielding electronic devices from the direct exposure to thermal and ultraviolet radiation as well as adverse environmental conditions.

### BRIEF DESCRIPTION OF THE SEVERAL VIEWS OF THE DRAWINGS

The accompanying drawings, which are incorporated in and form a part of the specification, illustrate a preferred embodiment of the present invention, and together with the description, serve to explain the principles of the invention. It is to be expressly understood that the drawings are for the purpose of illustration and description only and are not intended as a definition of the limits of the invention. In the drawings:

FIG. 1 is a front perspective view of the electronics shielding device in accordance with the teachings of the present disclosure;

FIG. 2 is a front view of the electronics shielding device in accordance with the teachings of the present disclosure;

FIG. 3 is a right side view of the electronics shielding device in accordance with the teachings of the present disclosure;

FIG. 4 is a top side view of the electronics shielding device in accordance with the teachings of the present disclosure;

FIG. 5 is a bottom side view of the electronics shielding device in accordance with the teachings of the present disclosure;

FIG. 6 is a back side view of the electronics shielding device in accordance with the teachings of the present disclosure; and

FIG. 7 is an environmental view of the electronics shielding device showing the shielding of the electronic device from thermal and ultraviolet rays in accordance with the teachings of the present disclosure.

### DETAILED DESCRIPTION OF THE INVENTION

Disclosed herein are devices and methods directed to shielding electronics from thermal, ultraviolet, and environmental exposure. The numerous innovative teachings of the present invention will be described with particular reference to several embodiments (by way of example, and not of limitation).

The present invention is directed to a vastly simpler and less expensive surveillance camera/electronics shade that prevents direct exposure to deteriorating thermal/ultra violet radiation and adverse environmental conditions while enhancing imaging by preventing solar glare. The device will significantly reduce supply chain electrical waste also referred to as waste electrical and electronic equipment (WEEE).

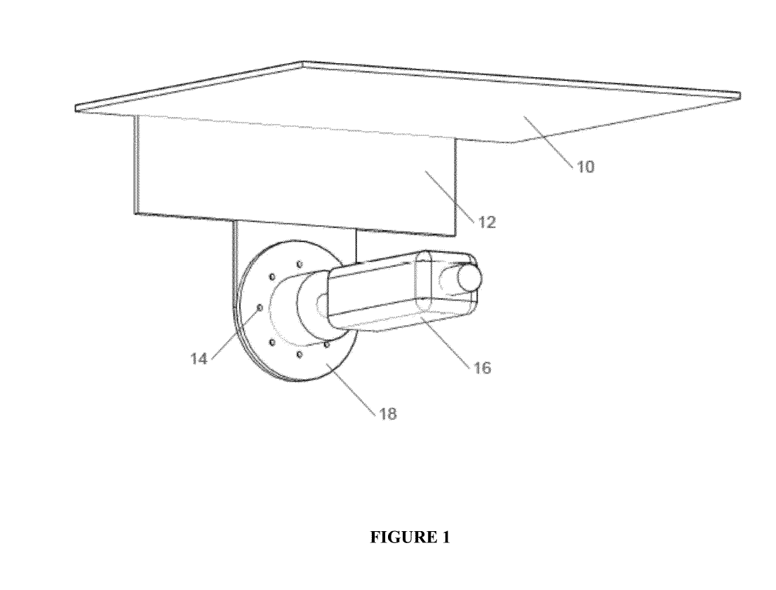

Reference is first made to FIG. 1, a front perspective view of the electronics shielding device in accordance with the teachings of the present disclosure. Illustrated in this figure is the electronic shielding device in a wall mounting configuration, shielding an installed video camera 16. In an embodiment, the device is comprised of a wall back plate element 12 and a shielding top plate element 10. The wall back plate element 12 and the shielding top plate element 10 are connected and form, in an embodiment, a right angle to each other. As shown in the figure, the upper portion of the wall back plate element 12 is connected to the back portion of the shielding top plate element 10. In other embodiments, the angle is not a right angle. The wall back plate element 12 and the shielding top plate element 10 may be separate elements or combined as one element and may be made from rigid materials such as, but not limited to, polymers, wood, metals, and composites. In an embodiment, the wall back plate element 12 and the shielding top plate element 10 may be releasably attached to allow the shielding top plate element 10 to be easily detached and replaced with another shielding top plate element 10. This may be accomplished with screws or bolts as an example and not a limitation. In other embodiments, the device is made from softer materials such as fabrics, stretch fabrics, and foams. The video camera's 12 wall mounting plate 18 is also shown. The wall mounting plate 18 may be a separate component or be configured as part of the video camera 16. The device is configured so that the device may shield various wall mounted electronic devices such as and not limited to, Wi-Fi transmitters, directional antennas, readers, amplifiers and all other electronic devices and communication equipment. Other various camera types that may be used, as examples and not limitations, are bullet, dome, pan tilt zooms (PTZ's), and wireless. The device is also easily configurable, by changing the size of the elements, for various application sizes such as shielding and protecting electronic, lighted, or LED billboards.

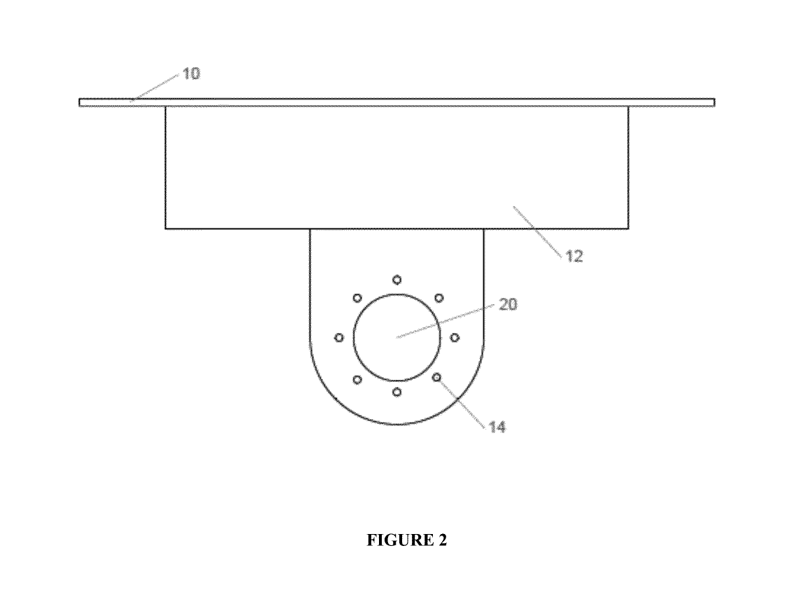

Reference is next made to FIG. 2, a front view of the electronics shielding device in accordance with the teachings of the present disclosure. Illustrated in this figure is the electronics shielding device without the camera components 12, 18. The shielding top plate element 10 may take many forms, sizes, and shapes and functions to block and shade the electronic device from direct exposure to deteriorating thermal/ultra violet radiation and adverse environmental conditions while enhancing imaging by preventing solar glare. In embodiments, the shielding top plate element 10 may have attached or embedded, solar panel elements to also serve as a power source for other devices.

The wall back plate element 12 functions to provide a structure for securing the device to a wall or an electronic device. The wall back plate element 12 may take many forms, sizes, and shapes. In embodiments and as shown in FIG. 2, the wall back plate element 12 is configured with an electronic device mounting opening 20. In other embodiments the wall back plate element 12 is also configured with electronic device bolt mounting holes 14. The electronic device mounting opening 20 and the electronic device bolt mounting holes 14 allows the electronic device 16 to be mounted directly to the wall back plate element 12 and not the wall itself. This allows the electronic device 16 to be seated flush with the wall back plate element 12 and not allow any gaps, cracks, or crevices between the electronic device 16 and the mounting surface, which is common when mounting against surfaces such as brick and masonry. By mounting the electronic device 16 flush against the wall back plate element 12, water incursion from the wall is eliminated or reduced.

In further embodiments, the wall back plate element 12 has a convex shape to further enhance the transmission and receiving properties of electronic equipment.

In yet other embodiments, the wall back plate element 12 is not configured with an electronic device mounting opening 20 or electronic device bolt mounting holes 14, allowing the electronic device 16 to be mounted directly to a wall with the electronics shielding device being mounted in a position, such as above, to allow the shielding of the electronics 16 from thermal, ultraviolet, and environmental exposure. This configuration also allows already wall mounted electronic devices 16 to have the electronics shielding device added without having to unmount and remount the already installed/wall mounted electronic device 16.

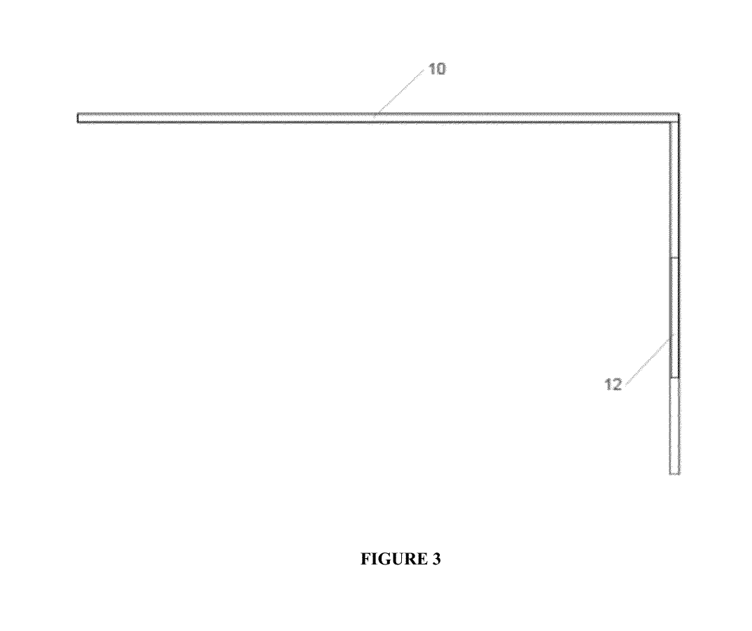

Reference is now made to FIG. 3, a right side view of the electronics shielding device in accordance with the teachings of the present disclosure. Illustrated in this figure is the device from a side view showing the thin signature or footprint of the device. In embodiments, the device is made to have a thickness of 1/16 to ¼ of an inch. In an embodiment, the device is made from aluminum having a 1/10 of an inch thickness. This allows the device to be very lightweight.

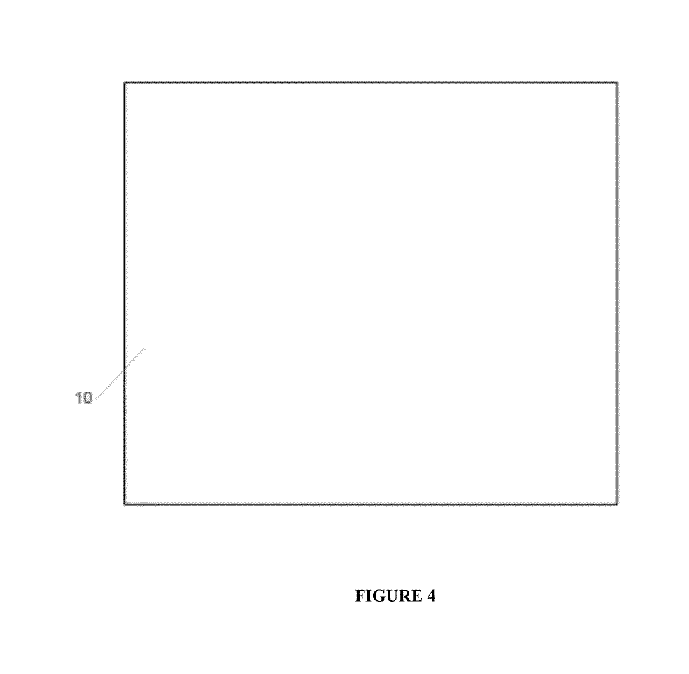

Reference is next made to FIG. 4, a top side view of the electronics shielding device in accordance with the teachings of the present disclosure. Illustrated in this figure is the shielding top plate element 10.

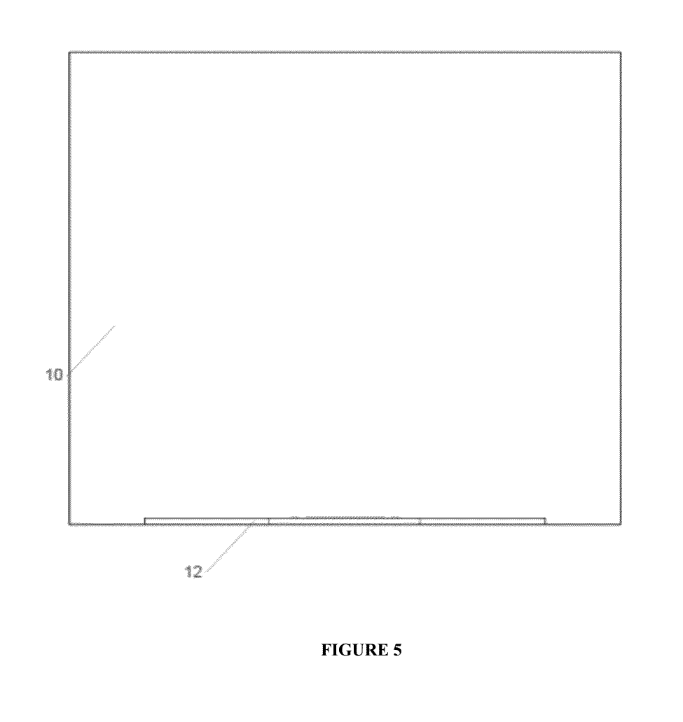

Reference is now made to FIG. 5, a bottom side view of the electronics shielding device in accordance with the teachings of the present disclosure. Illustrated in this figure is the electronics shielding device showing the shielding top plate element 10 as well as the wall back plate element 12.

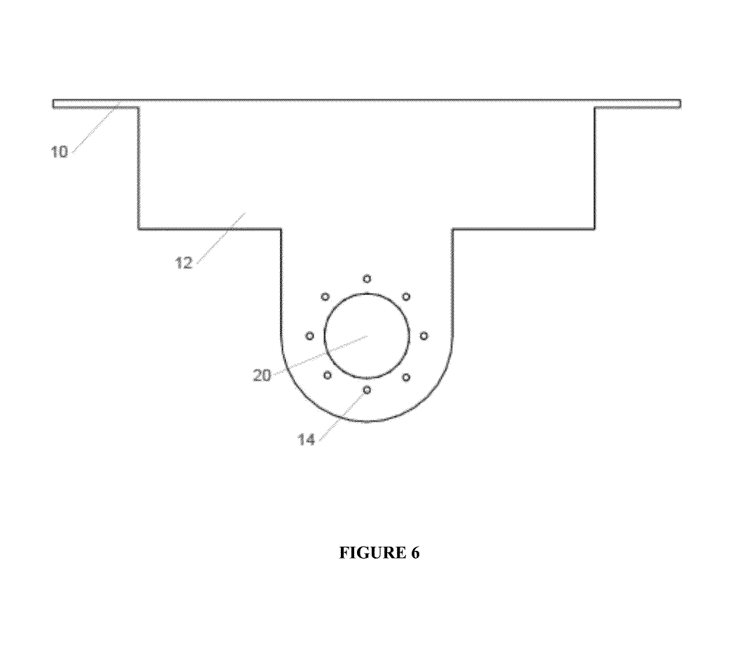

Reference is next made to FIG. 6, a back side view of the electronics shielding device in accordance with the teachings of the present disclosure. Illustrated in this figure is the electronics shielding device configured with the electronic device mounting opening 20 and the electronic device bolt mounting holes 14.

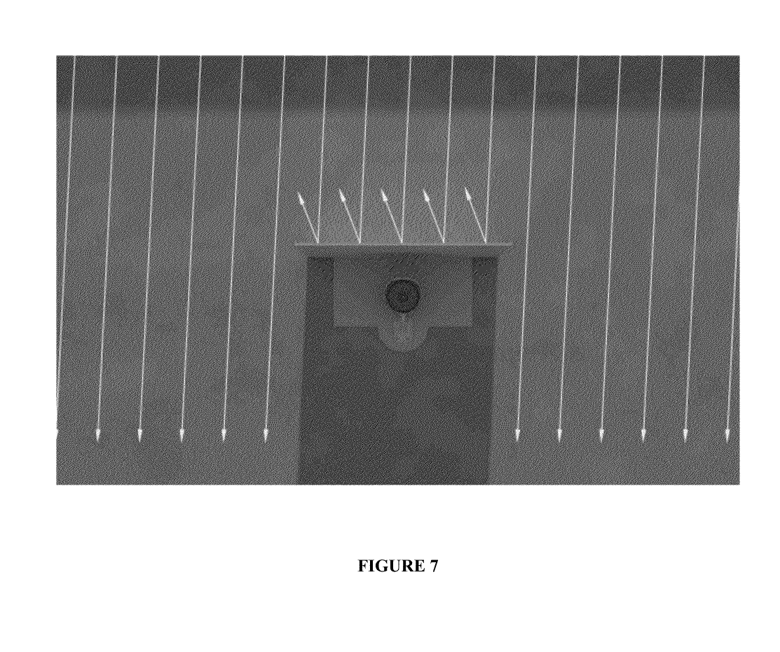

Reference is lastly made to FIG. 7, an environmental view of the electronics shielding device showing the shielding of the electronic device 16 from thermal and ultraviolet rays in accordance with the teachings of the present disclosure. Illustrated in this figure is the electronics shielding device protecting an electronic device 16 from direct exposure to thermal and ultraviolet radiation as well as adverse environmental conditions. This protects or shades the electronic device 16, preventing glare or visual degradation from direct sunlight exposure on the electronic device 16 and thereby enhancing the video or visual quality produced by the electronic device 16.

The disclosed devices and methods are generally described, with examples incorporated as particular embodiments of the invention and to demonstrate the practice and advantages thereof. It is understood that the examples are given by way of illustration and are not intended to limit the specification or the claims in any manner.

To facilitate the understanding of this invention, a number of terms may be defined below. Terms defined herein have meanings as commonly understood by a person of ordinary skill in the areas relevant to the present invention. Terms such as “a”, “an”, and “the” are not intended to refer to only a singular entity, but include the general class of which a specific example may be used for illustration. The terminology herein is used to describe specific embodiments of the invention, but their usage does not delimit the disclosed device or method, except as may be outlined in the claims.

Any embodiments comprising a one piece or multi piece device having the structures as herein disclosed with similar function shall fall into the coverage of claims of the present invention and shall lack the novelty and inventive step criteria.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific devices and methods described herein. Such equivalents are considered to be within the scope of this invention and are covered by the claims.

All publications, references, patents, and patent applications mentioned in the specification are indicative of the level of those skilled in the art to which this invention pertains. All publications, references, patents, and patent applications are herein incorporated by reference to the same extent as if each individual publication, reference, patent, or patent application was specifically and individually indicated to be incorporated by reference.

In the claims, all transitional phrases such as “comprising,” “including,” “carrying,” “having,” “containing,” “involving,” and the like are to be understood to be open-ended, i.e., to mean including but not limited to. Only the transitional phrases “consisting of” and “consisting essentially of,” respectively, shall be closed or semi-closed transitional phrases.

The devices and/or methods disclosed and claimed herein can be made and executed without undue experimentation in light of the present disclosure. While the device and methods of this invention have been described in terms of preferred embodiments, it will be apparent to those skilled in the art that variations may be applied to the systems and/or methods and in the steps or in the sequence of steps of the methods described herein without departing from the concept, spirit, and scope of the invention.

More specifically, it will be apparent that certain components, which are both shape and material related, may be substituted for the components described herein while the same or similar results would be achieved. All such similar substitutes and modifications apparent to those skilled in the art are deemed to be within the spirit, scope, and concept of the invention as defined by the appended claims.

What is claimed is:

1. A device for shielding electronics from thermal, ultraviolet, and environmental exposure comprising of:
a wall back plate element; and
a shielding top plate element;
wherein said wall back element is attached to said shielding top plate element.

2. The device of claim 1, wherein said wall back plate element and said shielding top plate element for a right angle to each other.

3. The device of claim 1, wherein said wall back plate element is further configured with an electronic device mounting opening.

4. The device of claim 1, wherein said wall back plate element is further configured with electronic device bolt mounting holes.

5. The device of claim 3, wherein said wall back plate element is further configured with electronic device bolt mounting holes.

6. The device of claim 1, wherein said wall back plate element is square.

7. The device of claim 1, wherein said wall back plate element is rectangular.

8. The device of claim 1, wherein said shielding top plate element is square.

9. The device of claim 1, wherein said shielding top plate element is rectangular.

10. The device of claim 6, wherein said shielding top plate element is square.

11. The device of claim 7, wherein said shielding top plate element is rectangular.

12. The device of claim 1, wherein said shielding top plate element is releasably attached to said wall back plate element.

13. A device for shielding electronics from thermal, ultraviolet, and environmental exposure comprising of:
a wall back plate element; and
a shielding top plate element;
wherein said wall back element is attached to said shielding top plate element along said wall back plate element's top portion and said shielding top plate element is attached to said wall back plate element along said shielding top plate element's back portion.

14. The device of claim 13, wherein said wall back plate element and said shielding top plate element for a right angle to each other.

15. The device of claim 13, wherein said wall back plate element is further configured with an electronic device mounting opening.

16. The device of claim 13, wherein said wall back plate element is further configured with electronic device bolt mounting holes.

17. The device of claim 15, wherein said wall back plate element is further configured with electronic device bolt mounting holes.

18. The device of claim 13, wherein said wall back plate element is rectangular and said shielding top plate element is rectangular.

18. The device of claim 3, wherein said shielding top plate element is further comprised of solar panel elements.

19. The device of claim 13, wherein said shielding top plate element is releasably attached to said wall back plate element.

20. A device for shielding electronics from thermal, ultraviolet, and environmental exposure comprising of:
a wall back plate element; and
a shielding top plate element;
wherein said wall back element is attached to said shielding top plate element along said wall back plate element's top portion and said shielding top plate element is attached to said wall back plate element along said shielding top plate element's back portion; and
wherein said wall back plate element is further configured with an electronic device mounting opening and electronic device bolt mounting holes; and
wherein said shielding top plate element is releasably attached to said wall back plate element.
